(19) United States
(12) Patent Application Publication
(10) Pub. No.: US 2026/0043858 A1
(43) Pub. Date: Feb. 12, 2026

(54) METHOD AND SYSTEM WITH DETERMINATION OF STATE OF CHARGE OF BATTERY

(71) Applicant: SAMSUNG ELECTRONICS CO., LTD., Suwon-si (KR)

(72) Inventors: Sagar BHARATHRAJ, Bengaluru (IN); Shashishekara Parampalli ADIGA, Bengaluru (IN)

(73) Assignee: SAMSUNG ELECTRONICS CO., LTD., Suwon-si (KR)

(21) Appl. No.: 19/289,325

(22) Filed: Aug. 4, 2025

(30) Foreign Application Priority Data
Aug. 7, 2024 (IN) 202441059631
Feb. 14, 2025 (KR) 10-2025-0019409

(51) Int. Cl. G01R 31/3835; G01R 31/374; H01M 10/42

(52) U.S. Cl. CPC G01R 31/3835; G01R 31/374; H01M 10/4285

(57) ABSTRACT

A method and system for determining a state of charge (SoC) of a battery are provided. The method includes determining, for one or more known SoC conditions of the battery, corresponding correlation constant values by correlating time derivatives of a plurality of rest period voltage values over a predefined time interval, generating, for the one or more known SoC conditions, reference sets including SoC values and the corresponding correlation constant values, determining, for an SoC condition of interest of the battery, a slope value of a rest period voltage profile of the battery at the SoC condition of interest, and comparing the slope value to the correlation constant values in the reference sets to determine the SoC of the battery for the SoC condition of interest.

### CROSS-REFERENCE TO RELATED APPLICATIONS

This application claims the benefit under 35 USC § 119(a) of Indian Patent Application number 202441059631 filed on Aug. 7, 2024, in the Indian Patent Office, and Korean Patent Application No. 10-2025-0019409 filed on Feb. 14, 2025, in the Korean Intellectual Property Office, the entire disclosures of which are incorporated herein by reference for all purposes.

### BACKGROUND

### 1. Field

The following examples relate to a battery, and more particularly, to a system and method with determination of a state of charge (SoC) of a battery.

### 2. Description of Related Art

Batteries play a fundamental role in powering the majority of devices, supplying the necessary energy for circuits and components to operate effectively. Among them, rechargeable batteries may be used due to their ability to be charged, discharged into a load, and subsequently recharged using an external power source.

One common type of rechargeable battery is the lithium-ion (li-ion) battery, which is known for its high energy density and longer lifespan. Li-ion batteries are widely used in various electronic devices. A key parameter associated with battery operation is the state of charge (SoC), which represents a percentage of a battery's total capacity that is currently available for use. SoC is typically expressed as a percentage, with 0% indicating a fully discharged battery and 100% indicating a fully charged battery. Accurate SoC estimation is critical for ensuring the safety, performance, and health of the battery during operation.

To estimate the SoC, the battery may be used in conjunction with an on-board system such as a battery management system (BMS). Typical SoC estimation systems and models may rely on monitoring the battery voltage and mapping the measured voltage to a pre-existing table of SoC and Voltage. In some known schemes, multiple SoC values are mapped to the same voltage level of the battery, leading to ambiguity and reduced accuracy in SoC estimation.

This issue may be particularly pronounced in lithium iron phosphate (LFP) based batteries. The SoC-Voltage profile for an LFP battery is substantially flat and for SoC values between 1-90%, the voltage varies within a narrow range of 3.2-3.3 V. Due to this narrow voltage range, such schemes are unreliable as there may be multiple SoC values corresponding to the same voltage value. This poses a significant challenge in electric vehicle applications, where batteries often experience long rest periods between uses, and accurate SoC information is critical for both vehicle performance and battery health.

Other known schemes for estimating the SoC are computation-heavy and require a lot of variables and data for processing. Despite their complexity, such schemes may still remain unreliable and inconsistent and put undesirable load on the BMS and slow down the performance of the BMS.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

The present disclosure provides a method and system for determining a state of charge (SoC) of a battery.

In one general aspect, a method of determining a state of charge (SoC) of a battery includes determining, for one or more known SoC conditions of the battery, corresponding correlation constant values by correlating time derivatives of a plurality of rest period voltage values over a predefined time interval; generating, for the one or more known SoC conditions, reference sets comprising SoC values of the battery at the one or more known SoC conditions and the corresponding correlation constant values; determining, for an SoC condition of interest of the battery, a slope value of a rest period voltage profile of the battery at the SoC condition of interest; and comparing the slope value to the correlation constant values in the reference sets to determine the SoC of the battery for the SoC condition of interest.

The determining of the corresponding correlation constant values may include determining a time-derivative of one of the rest period voltage values corresponding to a time segment within the predefined time interval.

The determining of the corresponding correlation constant values may include generating the rest period voltage profile for the rest period voltage values over the predefined time interval; splitting the rest period voltage profile into multiple profile-sections; and determining the corresponding correlation constant value by correlating time derivatives of the profile-sections.

The splitting of the rest period voltage profile may include determining a diffusivity time scale of the battery; and splitting the rest period voltage profile based on the diffusivity time scale.

The determining of the diffusivity time scale may include correlating a size of a battery particle of the battery and a diffusivity of the battery particle.

The splitting of the rest period voltage profile may include determining a radius of curvature of the rest period voltage profile; and splitting the rest period voltage profile based on the radius of curvature.

The determining of the corresponding correlation constant value may include splitting the rest period voltage profile into a first profile section and a second profile section; determining a first time-derivative of the first profile section; determining a second time-derivative of the second profile section; and summing the first time-derivative and the second time-derivative to obtain the corresponding correlation constant value.

The determining of the corresponding correlation constant values may include generating the rest period voltage profile by applying a logarithmic transformation to the rest period voltage values; splitting the rest period voltage profile into a first profile section and a second profile section; determining, for the first profile section, a first profile time-derivative of rest period voltage values of the first profile section; determining, for the second profile section, a second profile time-derivative of rest period voltage values of the second profile section; and summing the first profile time-derivative and the second profile time-derivative to obtain the corresponding correlation constant value.

The determining of the slope value may include determining a time-derivative of a section of the rest period voltage profile at the SoC condition of interest.

The determining of the slope value may include splitting the rest period voltage profile into multiple profile-sections; and correlating time derivatives of the profile-sections to determine the slope value.

The splitting of the rest period voltage profile may include determining a diffusivity time scale of the battery; and splitting the rest period voltage profile based on the diffusivity time scale.

The determining of the diffusivity time scale may include correlating a size of a battery particle of the battery and a diffusivity of the battery particle.

The splitting of the rest period voltage profile may include determining a radius of curvature of the rest period voltage profile; and splitting the rest period voltage profile based on the radius of curvature.

The determining of the slope value may include splitting the rest period voltage profile into a first profile section and a second profile section; determining a first time-derivative of the first profile section; determining a second time-derivative of the second profile section; and summing the first time-derivative and the second time-derivative to obtain the slope value.

The determining of the slope value may include generating the rest period voltage profile by applying a logarithmic transformation to the rest period voltage values; splitting the rest period voltage profile into a first profile section and a second profile section; determining, for the first profile section, a first profile time-derivative of rest period voltage values of the first profile section; determining, for the second profile section, a second profile time-derivative of rest period voltage values of the second profile section; and summing the first profile time-derivative and the second profile time-derivative to obtain the slope value.

The generating of the reference sets may include generating a plurality of the reference sets corresponding to a plurality of temperature values within a predefined temperature range.

The generating of the reference sets may include determining an average temperature of the battery during the predefined time interval; and generating a reference set corresponding to the determined average temperature of the battery.

The method may further include determining a current temperature of the battery at the SoC condition of interest; selecting a reference set based on the determined current temperature; and comparing the slope value to the correlation constant values in the selected reference set to determine the SoC of the battery for the SoC condition of interest.

In one general aspect, a system for determining an SoC of a battery includes a correlation constant values determining module configured to determine, for one or more known SoC conditions of the battery, corresponding correlation constant values by correlating time derivatives of a plurality of rest period voltage values over a predefined time interval; a reference sets generating module configured to generate, for the one or more known SoC conditions, reference sets comprising SoC values and the corresponding correlation constant values; a slope value determining module configured to determine, for an SoC condition of interest of the battery, a slope value of a rest period voltage profile of the battery; and a retrieval module configured to retrieve the SoC of the battery for the SoC condition of interest by comparing the slope value to the correlation constant values in the reference sets.

In one general aspect, provided is a non-transitory computer-readable storage medium storing instructions that, when executed by one or more processors, cause the one or more processors to determine, for one or more known SoC conditions of a battery, corresponding correlation constant values by correlating time derivatives of a plurality of rest period voltage values over a predefined time interval; generate, for the one or more known SoC conditions, reference sets comprising SoC values and the corresponding correlation constant values; determine, for an SoC condition of interest of the battery, a slope value of a rest period voltage profile of the battery; and compare the slope value to the correlation constant values in the reference sets to determine the SoC of the battery for the SoC condition of interest.

Other features and aspects will be apparent from the following detailed description, the drawings, and the claims.

### BRIEF DESCRIPTION OF THE DRAWINGS

FIG. 1 illustrates an example scenario depicting a battery and a connected load, according to one or more embodiments.

FIG. 2 illustrates an example method of determining a state of charge (SoC) of the battery, according to one or more embodiments.

FIG. 3A illustrates a graph depicting rest-period voltage values of the battery for one or more SoC conditions of the battery, according to one or more embodiments.

FIG. 3B illustrates a graph depicting a reduced rest-period voltage value for the graph of FIG. 3A, according to one or more embodiments.

FIG. 3C illustrates a graph depicting splitting of a rest-period voltage profile with reference to the exemplary graphs as in FIGS. 3A and 3B, according to one or more embodiments.

FIG. 4 illustrates an example method of determining the SoC of the battery, according to one or more embodiments.

FIG. 5A illustrates a graph depicting corresponding correlation constant values T with respect to the one or more known SoC conditions of the battery, according to one or more embodiments.

FIG. 5B illustrates a reference set including SoC values at the one or more known SoC conditions of the battery and the corresponding correlation constant values T, according to one or more embodiments.

FIG. 6 illustrates an example system for determining an SoC of the battery at an SoC condition of interest, according to one or more embodiments.

FIG. 7 illustrates an example battery-enabled device for determining an SoC of the battery, according to one or more embodiments.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

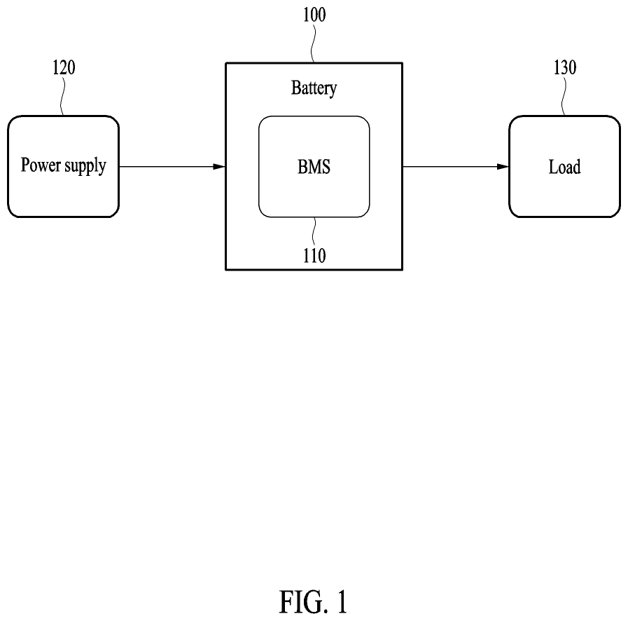

Hereinafter, a method and system for determining a state of charge (SoC) of a battery according to one or more embodiments are described in detail with reference to the attached FIGS. 1 through 7.

FIG. 1 illustrates a scenario depicting a battery 100 and a connected load, according to one or more embodiments.

The battery 100 may be a rechargeable battery, and may include a cell or a battery pack comprising a plurality of cells. A power supply 120 may be coupled to the battery 100 to charge the battery 100. A load 130 may use the power stored in the battery 100. The load 130 may be an electric vehicle, wherein the battery 100 serve as a primary energy source for vehicle propulsion. As a result of charging and discharging cycles, a state of charge (SoC) of the battery 100 changes.

The battery 100 may be a lithium-ion battery. In an example, the battery 100 may be a lithium iron phosphate (LiFePO) battery or lithium ferrophosphate (LFP) battery. An LFP battery is a type of lithium-ion battery using lithium iron phosphate as a cathode of the battery 100, and a graphitic carbon electrode as an anode of the battery 100.

The battery 100 may include a battery management system (BMS) 110. The BMS 110 may be an electronic system comprising one or more processors and memory configured to manage various functions of the battery 100. These functions may include monitoring and estimating conditions and states of the battery 100, such as state of health (SoH), SoC, and other performance metrics. The BMS 110 may be further configured to calculate and report data related to the status and performance the battery 100.

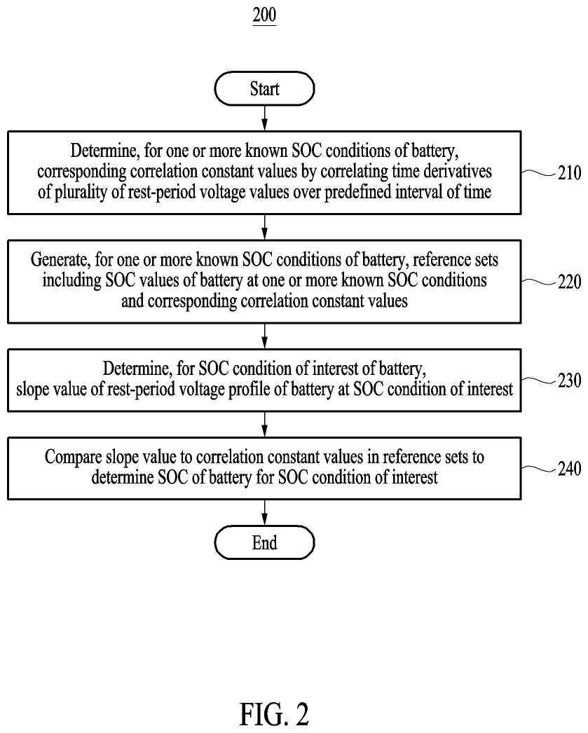

FIG. 2 illustrates a method 200 of determining an SoC of the battery 100, according to one or more embodiments.

The method 200 may include a sequence of operations, such as operations 210 through 240 shown in FIG. 2. In operation 210, the method 200 may include determining, for one or more known SoC conditions of the battery 100, corresponding correlation constant values T by correlating time derivatives of a plurality of rest-period voltage values measured over a predefined time interval. The one or more known SoC conditions of the battery 100 may include a state of the battery 100, wherein the SoC of the battery 100 is already known/established.

Various known schemes may be used to determine the SoC of the battery 100, including but not limited to: a voltage-based estimation scheme, wherein a voltage of a battery is used to estimate the SoC, a Coulomb counting scheme, wherein an electric charge in and out of a battery is counted based on current flow and time, a current integration scheme, wherein current measurements over time are integrated, an impedance spectroscopy scheme, wherein impedance characteristics are analyzed and the like may be used for estimating the SoC of the battery 100. In an example, the rest-period voltage values of the battery 100 may be measured over a predefined time interval when the battery 100 is at the one or more known SoC conditions. The BMS 110 may be configured to measure and report the rest-period voltage values of the battery 100.

In operation 220, the method 200 may include generating, for the one or more known SoC conditions of the battery 100, reference sets including SoC values of the battery 100 at the one or more known SoC conditions and the corresponding correlation constant values T. In operation 230, the method 200 may include determining, for an SoC condition of interest of the battery 100, a slope value of a rest-period voltage profile of the battery 100 at the SoC condition of interest. In operation 240, the method 200 may include comparing the slope value to the correlation constant values in the reference sets to determine the SoC of the battery 100 for the SoC condition of interest.

Each of the operations of the method 200 will be described in greater detail with respect to the following figures and examples.

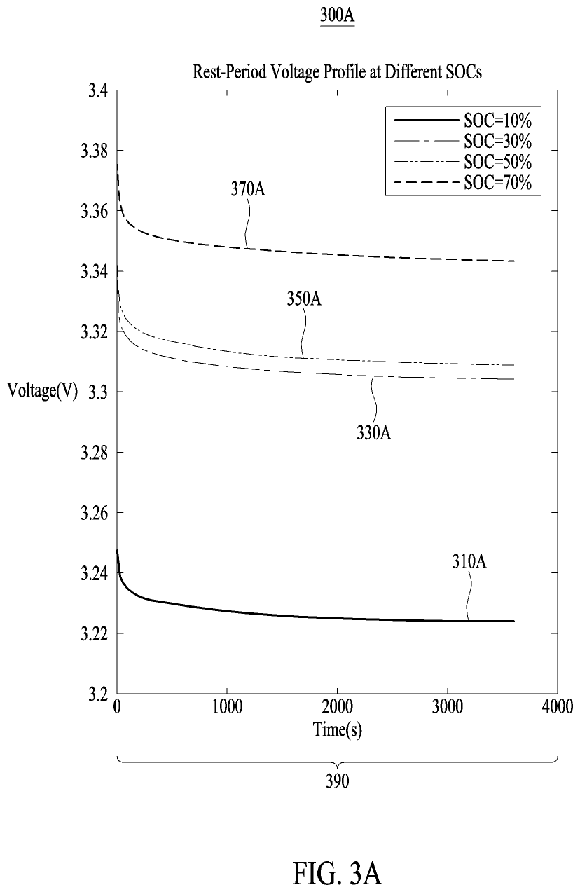

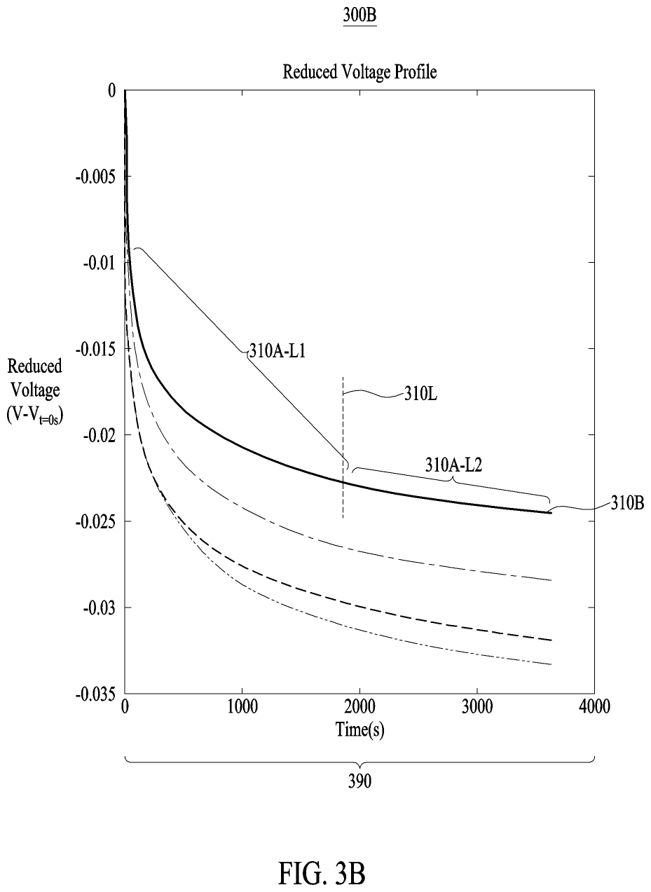

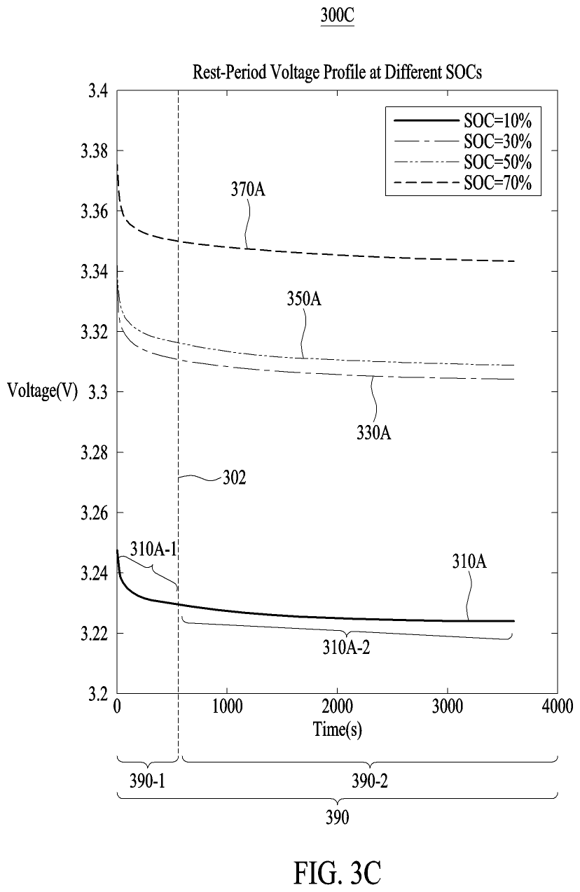

FIGS. 3A and 3B illustrate exemplary graphs 300A and 300B, respectively, depicting a plurality of rest-period voltage values of the battery 100 over a predefined time interval for one or more known SoC conditions of the battery 100, according to one or more embodiments.

The plurality of rest-period voltage values of the battery 100 may be voltage values of the battery 100 measured during a rest-period of the battery 100. The rest-period may be a time period during which a battery is either in an open rest condition (e.g., a state in which battery current is zero) or a float rest condition (e.g., a state in which a constant battery terminal voltage is maintained).

In an example, a current across terminals of the battery 100 may be compared to a predefined value/threshold to determine whether the battery 100 is in a rest period. The predefined value may vary depending on the configuration of the battery 100. For example, the predefined value may be 0.01 Amperes, 0.005 Amperes, or another suitable value.

The predefined time interval 390 may correspond to a part or all of the rest-period of the battery 100. The battery 100 may have the one or more known SoC conditions, wherein the SoC value of the battery 100 is known, such as an SoC value at 0%, an SoC value at 30%, or any other value between 0-100%.

FIG. 3A illustrates the graph 300A showing rest-period voltage values for the one or more SoC conditions of the battery 100, according to one or more embodiments.

Here, the SoC values may include 10% (SoC10), 30% (SoC30), 50% (SoC50) and 70% (SoC70). In an example, operation 210 of the method 200 may further include generating a rest-period voltage profile 310A, 330A, 350A, or 370A from the plurality of rest-period voltage values at each known SoC condition of the battery over the predefined time interval 390. Preferably, the rest-period voltage profiles are generated for all the SoC conditions of the battery 100. As shown in the graph 300A, for the SoC10, the battery 100 may have the plurality of rest-period voltage values represented as a rest-period voltage profile 310A over the predefined time interval 390. Herein, the predefined time interval 390 spans 0 to 4000 milliseconds. Similarly, profiles 330A, 350A, and 370A are shown for SoC30, SoC50, and SoC70, respectively.

FIG. 3B illustrates the graph 300B, which is a reduced rest-period voltage value graph derived from the graph 300A, according to one or more embodiments.

The graph 300B may be generated by subtracting an initial rest-period voltage value at the beginning of the rest-period from the rest-period voltage values in the rest-period profile, thereby normalizing the voltage data.

In an example, in operation 210 of the method 200, the corresponding correlation constant values T corresponding to the respective known SoC conditions of the battery 100 may be calculated by correlating time derivatives of the plurality of rest-period voltage values over the predefined time interval 390. For example, the method 200 may include calculating a corresponding correlation constant value T for the rest-period voltage profile 330A by correlating a time derivative of the plurality of rest-period voltage values of the rest-period voltage profile 330A over the predefined time interval 390.

In an example, operation 210 of the method 200 may further include calculating a time-derivative of one of the plurality of rest-period voltage values corresponding to a time segment (390-1 or 390-2 as shown in FIG. 3C) within the predefined time interval 390. For example, the predefined time interval 390 may be divided into time segments 390-1 of 0-500 milliseconds and 390-2 of 500-4000 milliseconds. The method 200 may include calculating a time-derivative of the rest-period voltage values corresponding to the time segment 390-1. Similarly, in another example, time segments, such as 0-800 milliseconds or 0-1000 milliseconds, within the total 0-4000 milliseconds time interval 390, may also be selected.

In an example, operation 210 of the method may further include splitting the rest-period voltage profile 310A, 330A, 350A, or 370A into multiple profile-sections and determining the corresponding correlation constant value T by correlating time derivatives of the multiple profile-sections as described with reference to FIG. 3C below.

FIG. 3C illustrates an example of splitting of the rest-period voltage profile 310A into sections with reference to the exemplary graphs as in FIGS. 3A and 3B, according to one or more embodiments.

As shown in FIG. 3C, a vertical line 302, parallel to the y-axis of the graph 300A, may be used to split the rest-period voltage profile 310A into multiple profile-sections, such as a profile-section 310A-1 and a profile-section 310A-2, corresponding to a time segment 390-1 and a time segment 390-2, respectively. The correlation constant value T may be calculated by correlating time derivatives of the profile-sections including the profile-section 310A-1 and the profile-section 310A-2. In an example, the time segment 390-1 and the time segment 390-2 are 0-500 milliseconds and 500-4000 milliseconds, respectively. These segments may also be selected based on system requirements or derived through the method 200. The time segment 390-1 and the time segment 390-2 may only be parts of the whole of the predefined interval of time 390. Specifically, the predefined interval of time 390 may be split/divided into more than two segments and any combination of these segments may be chosen in the analysis.

In an example, in operation 210, the splitting of the rest-period voltage profile 310A may further include determining a diffusivity time scale of the battery 100 and splitting the rest-period voltage profile 310A into sections (e.g., the profile-sections 310A-1 and 310A-2) based on the diffusivity time scale. The diffusivity time scale for the battery 100 may be calculated by correlating a radius R of an electrode particle of the battery 100 with a diffusivity D of the battery 100. The correlation to obtain diffusivity time scale may include dividing a square of the radius R of the electrode particle by the diffusivity D of the battery 100. Accordingly, the vertical line 302 may be positioned on the x-axis of the graph 300A based upon the diffusivity time scale to define appropriate time segments (e.g., the time segment 390-1 and the time segment 390-2) aligned with the diffusivity time scale.

Referring again to FIG. 3B, according to one or more embodiments, operation 210 of the method 200 may further include determining a radius of curvature of the rest-period voltage profile 310A and splitting the rest-period voltage profile 310A into profile-sections 310A-L1 and 310A-L2 based on a determined radius of curvature of the rest-period voltage profile 310A. For example, as shown in FIG. 3B, the rest-period voltage profile 310A may be split at a boundary line 310L into the profile-sections 310A-L1 and 310A-L2. For example, the section 310A-L1 may exhibit a smaller radius of curvature compared to the section 310A-L2, which has a flatter slope. This curvature-based splitting may enhance the precision of SoC estimation by isolating distinct dynamic behaviors in the voltage profile.

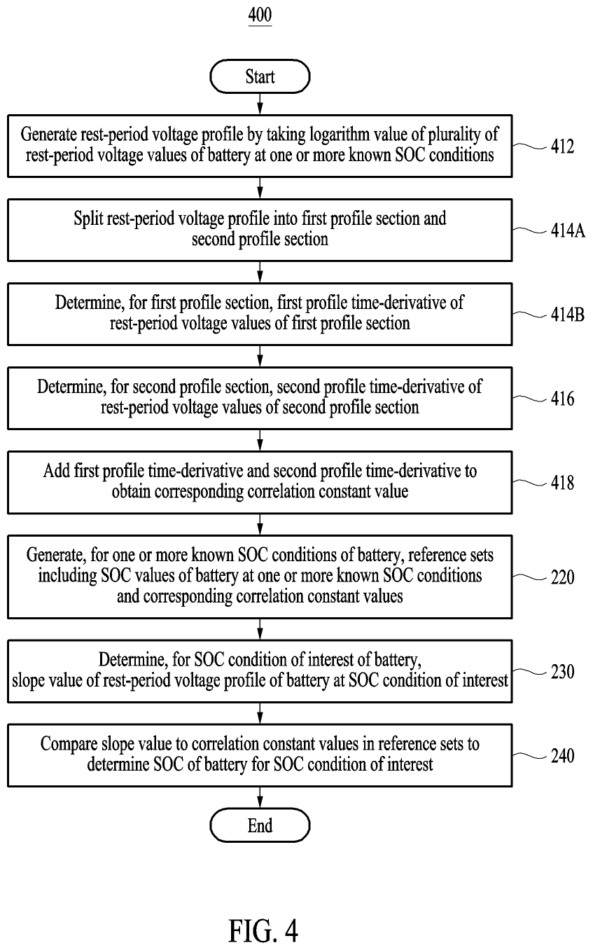

FIG. 4 illustrates a method 400 of determining the SoC of the battery 100, according to one or more embodiments.

The method 400 may include a sequence of operations, such as operations 220 through 240 and operations 412 through 418, as shown in FIG. 4.

In operation 412, the method 400 may include generating the rest-period voltage profile 310A by applying a logarithmic transformation to the plurality of rest-period voltage values of the battery 100 at the one or more known SoC conditions. Subsequently, in operation 414A, the method 400 may include splitting the generated rest-period voltage profile 310A into the first profile section 310A-L1 and the second profile section 310A-L2. In operation 414B, the method 400 may include determining, for the first profile section 310A-L1, a first profile time-derivative of rest-period voltage values of the first profile section 310A-L1. Similarly, in operation 416, the method 400 may include determining, for the second profile section 310A-L2, a second profile time-derivative of rest-period voltage values of the second profile section 310A-L2. In operation 418, the method 400 may include adding the first profile time-derivative and the second profile time-derivative to obtain the corresponding correlation constant value T. In an example, the remaining operations of the method 400 may be substantially similar to those described with respect to the method 200 as explained above.

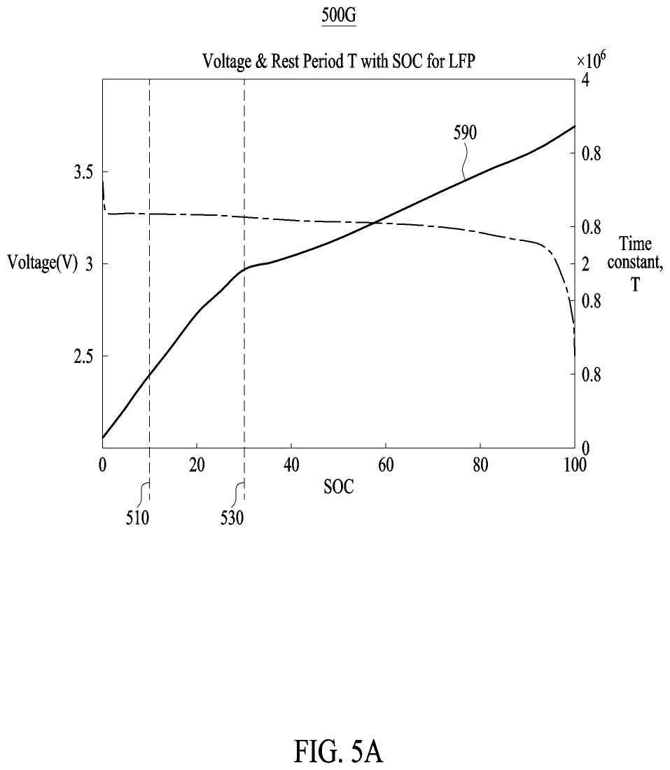

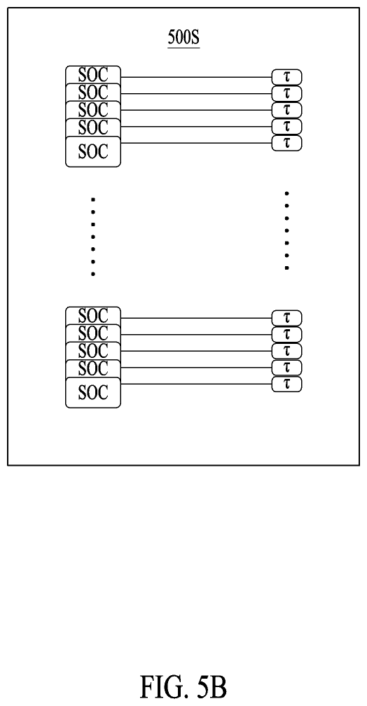

FIGS. 5A and 5B illustrate the method 200, wherein reference sets 500S are generated for the one or more known SoC conditions (e.g., SoC10, SoC30, SoC50, and SoC70) of the battery 100, according to one or more embodiments. The reference sets 500S may include SoC values of the battery 100 at the one or more known SoC conditions SoC10, SoC30, SoC50, and SoC70 and the corresponding correlation constant values T as determined in operation 210 described above.

FIG. 5A illustrates a graph 500G showing the corresponding correlation constant values T with respect to the one or more known SoC conditions SoC10, SoC30, SoC50, and SoC70 of the battery, according to one or more embodiments.

The corresponding correlation constant values T, calculated during operation 210, may be plotted as a plot line 590 in the graph 500G, representing the corresponding correlation constant values T with respect to the one or more known SoC conditions of the battery 100 (shown on the x-axis). For example, the SoC condition SoC10 of the battery 100 may be identified in the graph 500G by a line 510. Similarly, the SoC condition SoC30 of the battery 100 may be identified in the graph 500G by a line 530 and so forth. Following operations 210 and 220 of the method 200, the plot line 590 may be used to represent all the known SoC conditions of the battery 100 for any value between 0-100%.

FIG. 5B illustrates a reference set 500S including SoC values at the one or more known SoC conditions (e.g., SoC10, SoC30, SoC50, and SoC70) of the battery and the corresponding correlation constant values T, according to one or more embodiments.

The reference set 500S may serve as a data structure including SoC values of the battery 100 and the corresponding correlation constant values T. The graph 500G may be a visual representation of the reference set 500S.

In an example, the reference set 500S may be stored in a memory of the BMS 110 of the battery 100. The reference set 500S may be stored on a cloud-based server accessible by the BMS 110 of the battery 100. The stored reference set 500S may be retrieved for estimating the SoC of the battery 100.

In an example, operation 230 of the method 200 may include determining a slope value of a rest-period voltage profile at the SoC condition of interest of the battery 100. The SoC condition of interest may include a state of the battery 100 for which the SoC value is not known, and it is desired to know the SoC value for the SoC condition of interest. In such cases, the method 200 may be advantageously applied to determine the SoC value of the battery 100 at the SoC condition of interest.

In an example, operation 230 of the method 200 may further include determining a time-derivative of a section of the rest-period voltage profile 310A at the SoC condition of interest. For example, the rest-period voltage profile 310A may be a voltage profile of the battery 100 at the SoC condition of interest. A time derivative of the section 310A-L1 of the rest-period voltage profile 310A may be determined.

In an example, operation 230 of the method 200 may further include splitting the rest-period voltage profile at the SoC condition of interest into multiple profile-sections. For example, the rest-period voltage profile 310A may be a voltage profile of the battery 100 at the SoC condition of interest. The rest-period voltage profile 310A may be split into multiple profile-sections including the profile-sections 310A-L1 and 310A-L2. The rest-period voltage profile 310A may be split into multiple profile-sections other than the profile-sections 310A-L1 and 310A-L2. The rest-period voltage profile 310A may be split into multiple profile-sections including the profile-sections 310A-1 and 310A-2. The rest-period voltage profile 310A may be split into the multiple profile-sections other than the profile-sections 310A-1 and 310A-2. The rest-period voltage profile 310A may be split into two or more profile-sections, as appropriate.

In an example, operation 230 of the method 200 may include determining a diffusivity time scale of the battery 100 and splitting the rest-period voltage profile into the multiple profile-sections 310A-1 and 310A-2 based on the diffusivity time scale. In an example, operation 230 of the method 200 may further include correlating a particle size of the battery 100 with a diffusivity of the battery 100 to determine the diffusivity time scale of the battery 100. The particle size of the battery 100 may be an electrode particle size of the battery 100.

In an example, operation 230 of the method 200 may include determining a radius of curvature of the rest-period voltage profile 310A and splitting the rest-period voltage profile into the multiple profile-sections 310A-L1 and 310A-L2 based on the determined radius of curvature of the rest-period voltage profile 310A. For example, as shown in FIG. 3B, the rest-period voltage profile 310A may be split at the line 310L into the profile-sections 310A-L1 and 310A-L2, where the section 310A-L1 has a smaller radius of curvature as compared to the radius of curvature of the section 310A-L2. Specifically, the section 310A-L2 exhibits a flatter slope.

In an example, operation 230 of the method 200 may include determining a first time-derivative of the first profile section 310A-L1 and determining a second time-derivative of the second profile section 310A-L2. Subsequently, the method 200 may further include summing the first time-derivative and the second time-derivative to obtain the slope value for the SoC condition of interest of the battery 100.

In an example, operation 230 of the method 200 may include generating the rest-period voltage profile 310A by applying a logarithmic transformation to the rest-period voltage values at the SoC condition of interest of the battery 100. Subsequently, the method 200 may include splitting the rest-period voltage profile 310A into a first profile section 310A-L1 and a second profile section 310A-L2. The method 200 may further include determining, for the first profile section 310A-L1, a first profile time-derivative of rest-period voltage values of the first profile section 310A-L1 and determining, for the second profile section 310A-L2, a second profile time-derivative of rest-period voltage values of the second profile section 310A-L2. Subsequently, upon determination of the first and second profile time-derivatives, the method 200 may include summing the first profile time-derivative and the second profile time-derivative to obtain the slope value.

Operation 240 of the method 200 may include comparing the slope value to the correlation constant values T in the reference sets 500S to determine the SoC of the battery for the SoC condition of interest. Operation 240 of the method 200 may further include looking-up the slope value determined in operation 230 for the SoC condition of interest of the battery 100 in the reference set 500S.

For a given configuration of the battery 100, the slope value of the rest-period voltage profile 300A for a given SoC of the battery 100 may remain constant. Specifically, for the given configuration of the battery 100, the determined slope values at any SoC condition of interest may be the same as the stored T values in the reference set 500S generated in operation 220 of the method 200. The method 200 may use the determined slope value at the SoC condition of interest of the battery 100 and look-up for a matching or corresponding SoC value for a comparable stored T value in the reference set 500S. The looked-up value of SoC from the reference set 500S may be determined as the SoC value of the battery 100 at the SoC condition of interest of the battery 100.

In an example, the method 200 may include interpolating the SoC value of the battery from the reference sets 500, particularly when an exact match is not found.

Operation 220 of the method 200 may further include generating a plurality of reference sets 500S for a plurality of temperature values within a predefined temperature range for the one or more known SoC conditions of the battery. For the given configuration of the battery 100, since the value of the correlation constant T may vary with change in temperature, the method 200 may include generating and storing reference sets 500S at all probable operating temperatures of the battery 100.

Operation 220 of the method 200 may further include determining an average temperature of the battery 100 during the predefined time interval 390 and generating the reference set 500S corresponding to the determined average temperature of the battery 100.

In an example, the method 200 may further include determining a current temperature of the battery 100 at the SoC condition of interest, selecting the reference set 500S based on the determined current temperature, and comparing the slope value to the correlation constant values T in the selected reference set to determine the SoC of the battery for the SoC condition of interest. The reference set 500S may be selected from the plurality of reference sets 500S.

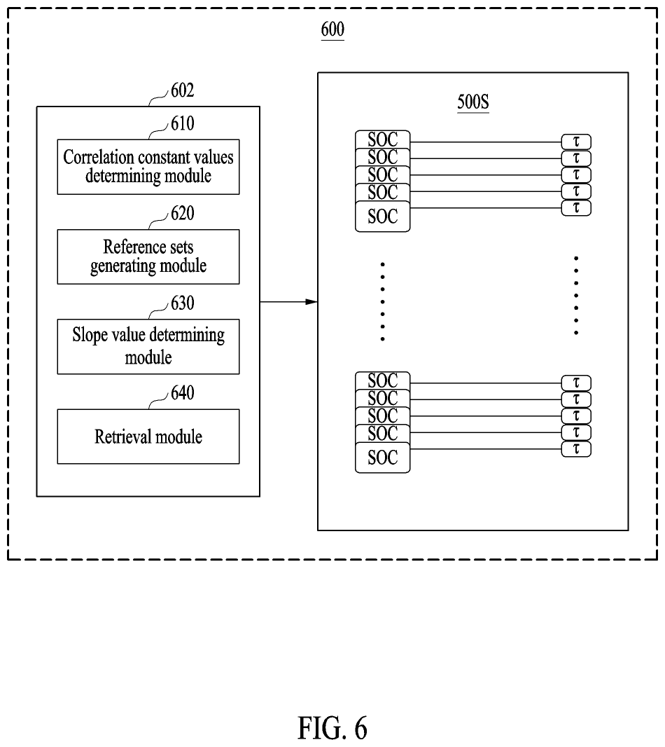

FIG. 6 illustrates a system 600 for determining an SoC of the battery 100 at an SoC condition of interest, according to one or more embodiments.

The system 600 may include one or more reference sets 500S and a plurality of modules 602 including a correlation constant values determining module 610, a reference sets generating module 620, a slope value determining module 630 and a retrieval module 640.

The modules 602 of the system 600 may be configured to perform the operations described in the methods 200 and 400, as detailed above in conjunction with FIGS. 2 through 5. The relevant descriptions are incorporated herein by reference and not repeated for brevity.

Each of the reference sets 500S may include SoC values of the battery 100 at the one or more known SoC conditions and corresponding correlation constant values T. The correlation constant values determining module 610 may determine, for one or more known SoC conditions of the battery 100, the corresponding correlation constant values T by correlating time derivatives of a plurality of rest period voltage values over a predefined time interval. The reference sets generating module 620 may generate, for the one or more known SoC conditions of the battery 100, the one or more reference sets including the SoC values of the battery 100 at the one or more known SoC conditions and the corresponding correlation constant values T. The slope value determining module 630 may determine, for the SoC condition of interest of the battery 100, a slope value of a rest period voltage profile of the battery 100 at the SoC condition of interest. The retrieval module 640 may retrieve the SoC of the battery 100 for the SoC condition of interest by comparing the slope value to the correlation constant values in the reference sets 500S.

In an example, the correlation constant values determining module 610 may determine a time-derivative of one of the plurality of rest period voltage values corresponding to a time segment within the predefined time interval. The correlation constant values determining module 610 may generate the rest period voltage profile for the plurality of rest period voltage values with respect to the predefined time interval, split the rest period voltage profile into multiple profile-sections and determine the corresponding correlation constant value T by correlating time derivatives of the multiple profile-sections.

In an example, the correlation constant values determining module 610 may determine a diffusivity time scale of the battery 100 and split the rest period voltage profile into the multiple profile-sections based on the diffusivity time scale. The correlation constant values determining module 610 may determine the diffusivity time scale by correlating a battery particle size of the battery 100 and a diffusivity of the battery particle.

In an example, the correlation constant values determining module 610 may determine a radius of curvature of the rest period voltage profile and split the rest period voltage profile into the multiple profile-sections based on the radius of curvature.

In an example, the correlation constant values determining module 610 may split the rest period voltage profile into a first profile section and a second profile section, calculate a first time-derivative of the first profile section and a second time-derivative of the second profile section, and sum the first time-derivative and the second time-derivative to obtain the corresponding correlation constant value T.

In an example, the correlation constant values determining module 610 may generate the rest period voltage profile by applying a logarithmic transformation to the rest period voltage values, split the rest period voltage profile into a first profile section and a second profile section, determine, for the first profile section, a first profile time-derivative of rest period voltage values of the first profile section, determine, for the second profile section, a second profile time-derivative of rest period voltage values of the second profile section, and sum the first profile time-derivative and the second profile time-derivative to obtain the corresponding correlation constant value T.

In an example, the slope value determining module 630 may determine a time-derivative of a section of the rest period voltage profile at the SoC condition of interest. The slope value determining module 630 may split the rest period voltage profile into multiple profile-sections and determine the slope value by correlating time derivatives of the multiple profile-sections. In an example, the slope value determining module 630 may determine a diffusivity time scale of the battery and split the rest period voltage profile into the multiple profile-sections based on the diffusivity time scale. The slope value determining module 630 may correlate a battery particle size of the battery with a diffusivity of the battery particle.

In an example, the slope value determining module 630 may determine a radius of curvature of the rest period voltage profile and split the rest period voltage profile into the multiple profile-sections based on the radius of curvature.

In an example, the slope value determining module 630 may split the rest period voltage profile into a first profile section and a second profile section, calculate a first time-derivative of the first profile section and a second time-derivative of the second profile section, and sum the first time-derivative and the second time-derivative to obtain the slope value.

The slope value determining module 630 may generate the rest period voltage profile by applying a logarithmic transformation to the rest period voltage values, split the rest period voltage profile into a first profile section and a second profile section, determine, for the first profile section, a first profile time-derivative of rest period voltage values of the first profile section, determine, for the second profile section, a second profile time-derivative of rest period voltage values of the second profile section, and sum the first profile time-derivative and the second profile time-derivative to obtain the slope value.

In an example, the reference sets generating module 620 may generate a plurality of reference sets. The plurality of reference sets may be generated for a plurality of temperature values in a predefined temperature range for the one or more known SoC conditions of the battery. The reference sets generating module 620 may determine an average temperature of the battery during the predefined time interval and generate the reference set corresponding to the determined average temperature of the battery.

In an example, the retrieval module 640 may determine a current temperature of the battery at the SoC condition of interest, select a reference set based on the determined current temperature and compare the slope value to the correlation constant values in the selected reference set to determine the SoC of the battery for the SoC condition of interest.

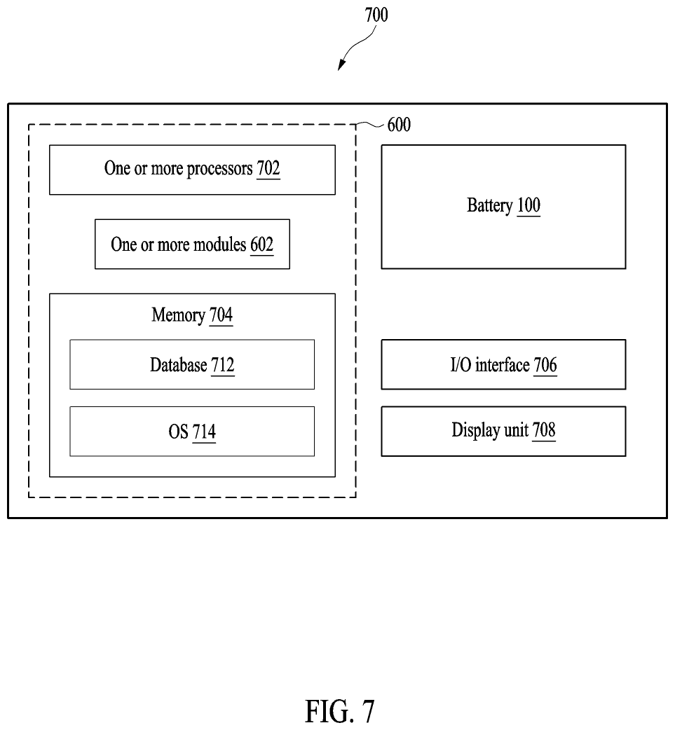

FIG. 7 illustrates a battery-enabled device 700 for determining an SoC of the battery 100, according to one or more embodiments.

In an example, the battery-enabled device 700 may correspond to the load 130 of the battery 100. Non-limiting examples of the battery-enabled device 700 may include an electric vehicle, a car, a motorbike, a truck and all such electronic/electrical devices utilizing rechargeable batteries.

The device 700 includes one or more processors 702 (collectively referred to as “processor”), a memory 704, an input/output (I/O) interface 706, a display unit 708, and the battery 100. The memory 704 may include a database 712 and an operating system (OS) 714. The device 700 may further include one or more modules 602. In an example, the I/O interface 706 may include the display unit 708. The processor 702, the memory 704, the battery 100, the display unit 708, and the I/O interface 706 may be communicatively coupled with each other.

In an example, the device 700 may incorporate the system 600, including the processor 702, modules 602, and memory 704, for determining the SoC of the battery 100 at the SoC condition of interest. The system 600 may be integrated within the device 700. In an example, one or more components of the system 600 may be implemented in a cloud-based architecture or on a physical server (not shown).

The processor 702 may be operatively coupled to the memory 704 and/or the modules 602 to process, execute, or perform a set of operations. The processor 702 may include a data processor for executing processes in a virtual storage area network. The processor 702 may include specialized processing units such as integrated system (bus) controllers, memory management control units, floating point units, graphics processing units, digital signal processing units, and/or other hardware accelerators. The processor 702 may be implemented using a central processing unit (CPU), a graphics processing unit (GPU), or both. The processor 702 may be one or more general processors, digital signal processors, application-specific integrated circuits, field-programmable gate arrays, servers, networks, digital circuits, analog circuits, combinations thereof, or other devices for analyzing and processing data. The processor 702 may execute one or more instructions, such as code generated manually to perform one or more operations disclosed herein throughout the disclosure such as the operations of the methods 200 and 400 as described herein.

The processor 702 may cooperate with the modules 602 to perform specific operations. The term “module” or “modules” used herein may refer to a unit implemented in hardware, software, firmware or any combination thereof. The “module” may be interchangeably used with a term such as logic, a logical block, a component, and the like. The “module” may represent a minimum device component for performing one or more designated functions. In an example, the processor 702 may control the modules 602 to execute a specific set of operations described in the disclosure.

The modules 602 may perform their designated functions in conjunction with the memory 704 and the processor 702. The memory 704 may be communicatively coupled to the processor 702. The modules 602 may be included within the memory 704. The memory 704 may store data, and instructions executable by the processor 702. The memory 704 may store the reference sets 500S.

The modules 602 may include executable instructions configured to cause the system 600 to perform any one or more of the methods disclosed herein using the data stored in the memory 704. In an example, the modules 602 may be hardware units that may be positioned outside the memory 704.

The memory 704 may include any suitable non-transitory computer-readable medium, such as volatile memory (e.g., SRAM, DRAM), and/or non-volatile memory (e.g., ROM, EEPROM, flash, hard disks, optical or magnetic media). The memory 704 may be communicatively coupled with the processor 702 to store bitstreams or processing instructions for completing the process. Further, the memory 704 may include an operating system 714 for performing one or more tasks of the battery-enabled device 700, as performed by a generic OS in the communications domain or a standalone device. In an example, the memory 704 may include a database 712 configured to store information as required by the modules 602 and the processor 702 to perform one or more functions for determining the SoC of the battery 100 of the battery-enabled device 700.

The memory 704 may store instructions executable by the processor 702. The functions, acts, or tasks illustrated in the figures or described may be performed by the processor 702, in conjunction with the modules 602, for executing the instructions stored in the memory 704. The functions, acts, or tasks are independent of the particular type of instruction set, storage media, processor, or processing strategy and may be performed by software, hardware, integrated circuits, firmware, micro-code, and the like, operating alone or in combination. Likewise, processing strategies may include multiprocessing, multitasking, parallel processing, and the like.

For brevity, the architecture and standard operations of the memory 704 and the processor 702 are omitted. The memory 704 may be configured to store information as required by the modules 602 and/or the processor 702 to perform the methods described herein.

The battery-enabled device 700 may also include one or more batteries 100 to fulfil the electrical energy required by the battery-enabled device 700. The battery 100 may correspond to a rechargeable lithium-ion battery including one or more electrochemical cells. Each of the one or more electrochemical cells may convert chemical energy into electrical energy through electrochemical reactions. During charging of the battery 100, an external power source (such as the power supply 120) may be connected to the device 700, in particular the battery 100, to cause a flow of a plurality of electrons from a positive electrode (i.e., the positive terminal) to a negative electrode (i.e., the negative terminal) in the one or more electrochemical cells. Simultaneously, a plurality of ions may migrate from the negative electrode to the positive electrode to complete the electrochemical reactions.

The I/O interface 706 may be hardware or software components that enable data communication between the battery-enabled device 700 and any other devices or systems. The I/O interface 706 may serve as a communication medium for exchanging information with the other devices or systems.

The display unit 708 may be a display screen, a monitor, a graphical user interface, or similar output interface. The display unit 708 may be an output device that visually presents information to a user. The display unit 708 may form an integral part of various electronic devices, including computers, smartphones, tablets, cars, and more. The display unit 708 may be configured to render visual content and provide the graphical user interface for interacting with the battery-enabled device 700.

Further, the present disclosure may also contemplate a computer-program product that includes instructions or receives and executes instructions responsive to a propagated signal. Further, the instructions may be transmitted or received over the network via a communication port or interface. The communication port may be a part of the processor 702 or may be a separate component. The connection with the network may be a physical connection, such as a wired ethernet connection, or may be established wirelessly.

The present disclosure may include a non-transitory computer-readable medium encoded with executable instructions. The executable instructions, when executed by the processor 702, may cause the processor 702 to perform the methods 200 and 400 as disclosed herein. Examples of computer-readable mediums include ROM or erasable, electrically programmable read-only memory (EEPROM), floppy disks, hard disk drives and compact disk read-only memories (CD-ROMs) or digital versatile disks (DVDs).

The system 600 and the methods 200 and 400 as disclosed may provide a comprehensive approach to determine the SoC of the battery 100. This configuration may ensure accurate estimation of the SoC of the battery 100.

Referring now to the technical abilities and effectiveness of the methods 200 and 400 and the system 600 as disclosed herein, the present disclosure may provide the technical advantages including simplifying and accurately determining the SoC of the battery 100. The method of the disclosure may be useful where the SoC-open circuit potential (OCP) profile is flat such as LFP batteries and where the battery has regular rest periods such as batteries used in electric vehicles, electric bikes and the like.

The methods and system herein may advantageously apply the signature profile of the rest period voltage at various SoC condition of the battery to generate reference sets for retrieving the SoC values of the battery without the need of heavy computations/processing. The load on the BMS may also be reduced. The method is based on signature voltage profile linked to the solid-phase diffusivity. This may obviate the need for any on-board electrochemical-thermal (ECT) model. The method proposed by the disclosure may be easily deployable on existing BMS without the usage of any computational resources of the BMS. The on-board conventional method on the BMS may still be used to confirm the SoC values. Conversely, the methods and system of the disclosure may be used for correcting the SoC estimation values obtained by conventional systems such as an already existing ECT model in the BMS.

While specific language has been used to describe the present disclosure, any limitations arising on account thereto, are not intended. As would be apparent to a person in the art, various working modifications may be made to the methods 200 and 400 to implement the inventive concept as described herein. The drawings and the foregoing description provide examples of embodiments. Those skilled in art will appreciate that one or more of the described elements may well be combined into a single functional element. Alternatively, certain elements may be split into multiple functional elements. Elements from an example may be added to another example.

The processors, the memories, the displays, interfaces, batteries, and other apparatuses, devices, units, and components described herein, including descriptions with respect to respect to FIGS. 1-7, are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit (ALU), a digital signal processor (DSP), a microcomputer, a programmable logic controller, a field-programmable gate array (FPGA), a programmable logic array (PLU), a microprocessor, or any other device or combination of devices that is configured to respond to and execute instructions (e.g., code or coding) in a defined manner to achieve a desired result. In one example, a processor or computer includes, or is connected to, one or more memories storing the instructions or software that are executed by the processor or computer. Hardware components implemented by a processor or computer may execute the instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both, and thus while some references may be made to a singular processor or computer, such references also are intended to refer to multiple processors or computers. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing. Thus, references to a processor herein mean processing circuitry (e.g., circuitry that includes one or more processing element(s) circuits). One or more processors comprising processing circuitry also refers to each processor comprising processing circuitry, as well as some or all of the one or more processors comprising the same processing circuitry. In addition, processors(s) and controller(s), as a non-limiting example, do not mean human processing or human control, but rather, refer to hardware components as described herein, as non-limiting examples.

The methods illustrated in, and discussed with respect to, FIGS. 1-7 that perform the operations described in this application are performed by computing hardware, for example, by one or more processors or computers, implemented as described above implementing the instructions (e.g., computer or processor/processing device readable instructions) or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations. References to a processor, or one or more processors, as a non-limiting example, configured to perform two or more operations refers to a processor or two or more processors being configured to collectively perform all of the two or more operations, as well as a configuration with the two or more processors respectively performing any corresponding one of the two or more operations (e.g., with a respective one or more processors being configured to perform each of the two or more operations, or any respective combination of one or more processors being configured to perform any respective combination of the two or more operations). Likewise, a reference to a processor-implemented method is a reference to a method that is performed by one or more processors or other processing or computing hardware of a device or system.

The instructions or software to control computing hardware, for example, one or more processors or computers, to implement the hardware components and perform the methods as described above may be written as computer programs, code segments, or other executable instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. Thus, references herein to storage media mean storage media hardware, and does not mean to transitory media, nor a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as a multimedia card or a micro card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A method of determining a state of charge (SoC) of a battery, the method comprising:
determining, for one or more known SoC conditions of the battery, corresponding correlation constant values by correlating time derivatives of a plurality of rest period voltage values over a predefined time interval;
generating, for the one or more known SoC conditions, reference sets comprising SoC values of the battery at the one or more known SoC conditions and the corresponding correlation constant values;
determining, for an SoC condition of interest of the battery, a slope value of a rest period voltage profile of the battery at the SoC condition of interest; and
comparing the slope value to the correlation constant values in the reference sets to determine the SoC of the battery for the SoC condition of interest.

2. The method of claim 1, wherein the determining of the corresponding correlation constant values comprises determining a time-derivative of one of the rest period voltage values corresponding to a time segment within the predefined time interval.

3. The method of claim 1, wherein the determining of the corresponding correlation constant values comprises:
generating the rest period voltage profile for the rest period voltage values over the predefined time interval;
splitting the rest period voltage profile into multiple profile-sections; and
determining the corresponding correlation constant value by correlating time derivatives of the profile-sections.

4. The method of claim 3, wherein the splitting of the rest period voltage profile comprises:
determining a diffusivity time scale of the battery; and
splitting the rest period voltage profile based on the diffusivity time scale.

5. The method of claim 4, wherein the determining of the diffusivity time scale comprises correlating a size of a battery particle of the battery and a diffusivity of the battery particle.

6. The method of claim 3, wherein the splitting of the rest period voltage profile comprises:
determining a radius of curvature of the rest period voltage profile; and
splitting the rest period voltage profile based on the radius of curvature.

7. The method of claim 3, wherein the determining of the corresponding correlation constant value comprises:
splitting the rest period voltage profile into a first profile section and a second profile section;
determining a first time-derivative of the first profile section;
determining a second time-derivative of the second profile section; and
summing the first time-derivative and the second time-derivative to obtain the corresponding correlation constant value.

8. The method of claim 3, wherein the determining of the corresponding correlation constant values comprises:
generating the rest period voltage profile by applying a logarithmic transformation to the rest period voltage values;
splitting the rest period voltage profile into a first profile section and a second profile section;
determining, for the first profile section, a first profile time-derivative of rest period voltage values of the first profile section;
determining, for the second profile section, a second profile time-derivative of rest period voltage values of the second profile section; and
summing the first profile time-derivative and the second profile time-derivative to obtain the corresponding correlation constant value.

9. The method of claim 1, wherein the determining of the slope value comprises determining a time-derivative of a section of the rest period voltage profile at the SoC condition of interest.

10. The method of claim 1, wherein the determining of the slope value comprises:
splitting the rest period voltage profile into multiple profile-sections; and
correlating time derivatives of the profile-sections to determine the slope value.

11. The method of claim 10, wherein the splitting of the rest period voltage profile comprises:
determining a diffusivity time scale of the battery; and
splitting the rest period voltage profile based on the diffusivity time scale.

12. The method of claim 11, wherein the determining of the diffusivity time scale comprises correlating a size of a battery particle of the battery and a diffusivity of the battery particle.

13. The method of claim 10, wherein the splitting of the rest period voltage profile comprises:
determining a radius of curvature of the rest period voltage profile; and
splitting the rest period voltage profile based on the radius of curvature.

14. The method of claim 10, wherein the determining of the slope value comprises:
splitting the rest period voltage profile into a first profile section and a second profile section;
determining a first time-derivative of the first profile section;
determining a second time-derivative of the second profile section; and
summing the first time-derivative and the second time-derivative to obtain the slope value.

15. The method of claim 1, wherein the determining of the slope value comprises:
generating the rest period voltage profile by applying a logarithmic transformation to the rest period voltage values;
splitting the rest period voltage profile into a first profile section and a second profile section;
determining, for the first profile section, a first profile time-derivative of rest period voltage values of the first profile section;
determining, for the second profile section, a second profile time-derivative of rest period voltage values of the second profile section; and
summing the first profile time-derivative and the second profile time-derivative to obtain the slope value.

16. The method of claim 1, wherein the generating of the reference sets comprises generating a plurality of the reference sets corresponding to a plurality of temperature values within a predefined temperature range.

17. The method of claim 1, wherein the generating of the reference sets comprises:
determining an average temperature of the battery during the predefined time interval; and
generating a reference set corresponding to the determined average temperature of the battery.

18. The method of claim 1, further comprising:
determining a current temperature of the battery at the SoC condition of interest;
selecting a reference set based on the determined current temperature; and
comparing the slope value to the correlation constant values in the selected reference set to determine the SoC of the battery for the SoC condition of interest.

19. A system for determining an SoC of a battery, the system comprising:
a correlation constant values determining module configured to determine, for one or more known SoC conditions of the battery, corresponding correlation constant values by correlating time derivatives of a plurality of rest period voltage values over a predefined time interval;
a reference sets generating module configured to generate, for the one or more known SoC conditions, reference sets comprising SoC values and the corresponding correlation constant values;
a slope value determining module configured to determine, for an SoC condition of interest of the battery, a slope value of a rest period voltage profile of the battery; and
a retrieval module configured to retrieve the SoC of the battery for the SoC condition of interest by comparing the slope value to the correlation constant values in the reference sets.

20. A method of determining a state of charge (SoC) of a battery, the method comprising:
generating a rest period voltage profile for a plurality of rest period voltage values measured over a predefined time interval during a rest period of the battery;
splitting the rest period voltage profile into at least a first profile section and a second profile section based on at least one of a diffusivity time scale derived from a battery particle size and diffusivity of the battery, and a radius of curvature of the rest period voltage profile;
calculating a first time-derivative of rest period voltage values of the first profile section;
calculating a second time-derivative of rest period voltage values of the second profile section;
determining a correlation constant value by summing the first time-derivative and the second time-derivative;
generating a reference set comprising known SoC values of the battery and corresponding correlation constant values determined at the known SoC conditions;
determining a slope value for an SoC condition of interest by repeating the splitting and calculating steps for a rest period voltage profile at the SoC condition of interest; and
determining the SoC for the SoC condition of interest by comparing the slope value to the correlation constant values in the reference set.
